(19) United States
(12) Patent Application Publication
(10) Pub. No.: US 2009/0016202 A1
(43) Pub. Date: Jan. 15, 2009

(54) METHOD OF PRODUCING A PHOTOELECTRIC TRANSDUCER AND OPTICAL PICK UP

(75) Inventors: Graciano De Oliveira, Dijon (FR); Rodrigue Boucher, Quetigny (FR); Herve Saillio, Dijon (FR)

Correspondence Address: Joseph J Laks;Thomson Licensing Inc, Patent Operations, P O Box 5312, Princeton, NJ, 08543-5312, US

(73) Assignee: Thomson Licensing, Boulogne-Billancourt (FR)

(21) Appl. No.: 10/580,187

(22) PCT Filed: Nov. 25, 2004
(86) PCT No.: PCT/EP2004/053098

§ 371 Date: Sep. 22, 2008

(30) Foreign Application Priority Data
Nov. 28, 2003 (FR) 03/50936

(51) Int. Cl. G11B 9/00; H01L 21/00; H01L 31/00

(52) U.S. Cl. 369/126; 438/64; 257/433; 257/E21.001; 257/E31.001

(57) ABSTRACT

A photoelectric transducer comprises a board, which carries at least an optical sensor on one face, and a spacer defining a recess that houses the optical sensor. The recess is at least partly filled with an optical glue. To mount the transducer in an optical pick up for an optical disk, the spacer is fastened to an optical body of the pick up.

The invention relates to a device suitable for reading an optical disc and to a photoelectric transducer, for example for such a device.

A photoelectric transducer makes it possible to convert a signal, coded in optical form, for example by variations in the intensity of a light ray, into an electrical signal, which can be more easily used by electronic circuits. Such a transducer comprises in general an optical sensor that carries out the actual conversion of the light signal into an electrical signal.

A photoelectric transducer is used, for example, in an optical disc read device. In such a device, a light ray is in fact modulated by the inscriptions etched on a rotating optical disc in such a way that the modulated ray represents the information written on the disc. One may refer to U.S. Pat. No. 5,872,749 for background information on the technical principle of an optical disc read device.

The modulated ray is then transmitted to the optical sensor of the transducer via optical means carried by an optical body which is part of an optical pick up designed to read data from (and/or write data to) the disc. The optical means allow correct shaping of the beam, especially its focusing onto the optical sensor. The modulation of the light ray is thus converted into an electrical signal, which therefore itself also represents the information written on the disc and can thus be processed by the electronic circuits of the device.

It will consequently be understood that the design of the photoelectric transducer and the way in which it is combined with the optical body are particularly important and tricky aspects.

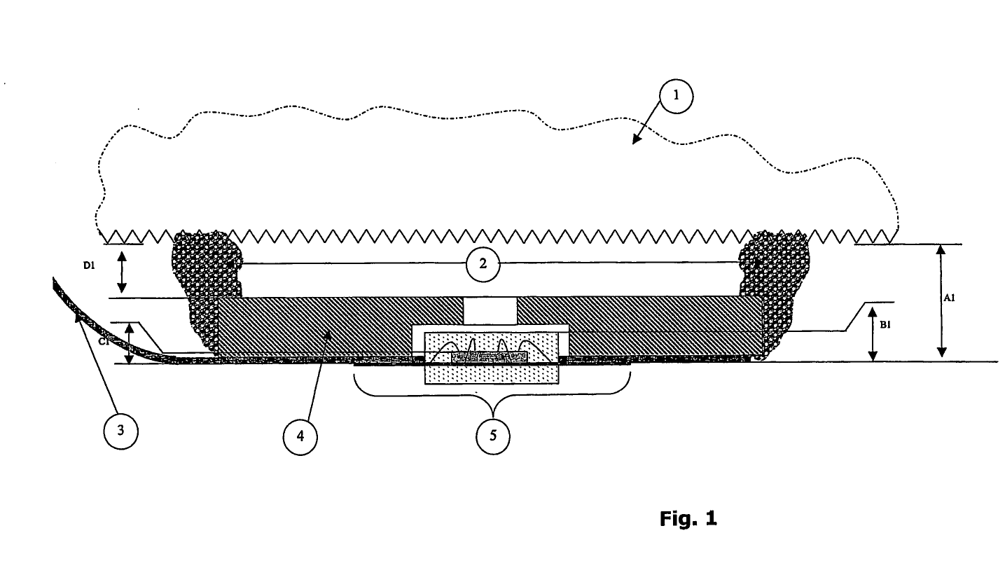

According to a first possible design shown in FIG. 1, the optical sensor is packaged in a transparent body, which is itself encapsulated in a package 5 composed of a plate 4 and a flexible board 3 which is extended by a connector. The plate 4 has an opening opposite the optical sensor, which allows passage of the light ray received from the optical body 1 which is part of an optical pick up (not illustrated).

The package 5 may easily be mounted on the optical body 1 by fastening the plate 4 to the optical body 1, for example by means of a fastening cement 2. The cost of this solution is, however, relatively high, especially owing to the complexity of the construction of the package 5.

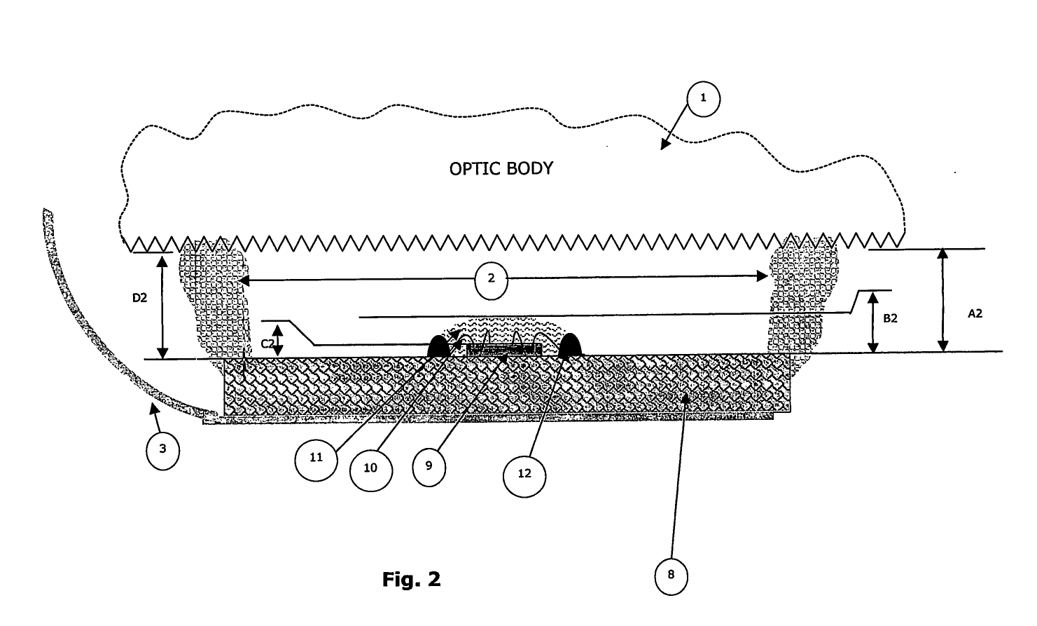

Consequently, a less expensive solution has been proposed, this being shown in FIG. 2. Another solution of this type is also described in U.S. Pat. No. 5,962,810.

According to the solution shown in FIG. 2, the optical sensor is housed on a printed circuit board 8 (or PCB) which is mounted on the flexible board 3. A bead of glue 12 is deposited around the integrated circuit 9 that carries the sensor, and thus defines a cavity that houses the sensor and is filled with an optical glue 11. The printed circuit board 8 is fixed directly to the optical body 1.

However, this simple solution has drawbacks.

Firstly, for the same integrated circuit/optical body distance (A1 in FIG. 1, A2 in FIG. 2, A1=A2), the distance D2 separating the printed circuit board 8 from the optical body 1 in FIG. 2 is greater than the distance D1 separating the plate 4 from the optical body 1 in FIG. 1 owing to the absence of such a plate in FIG. 2. This greater distance makes it necessary to use a larger amount of cement in FIG. 2 and reduces the mechanical stability of the system, this being especially prejudicial when mounting the transducer on the optical body 1.

Secondly, the printed circuit board 8 and the optical body 1 are, because of their respective functions, made from different materials, which make the fastening of these two elements more complicated and generally weaker.

In addition, the bead of glue 12 is relatively irregular, unless there are considerable forces during its deposition, and its shape in cross section is by nature rounded. The outer surface of the optical glue 11 will therefore not be plane, but will instead form a convex or concave meniscus depending on the conditions.

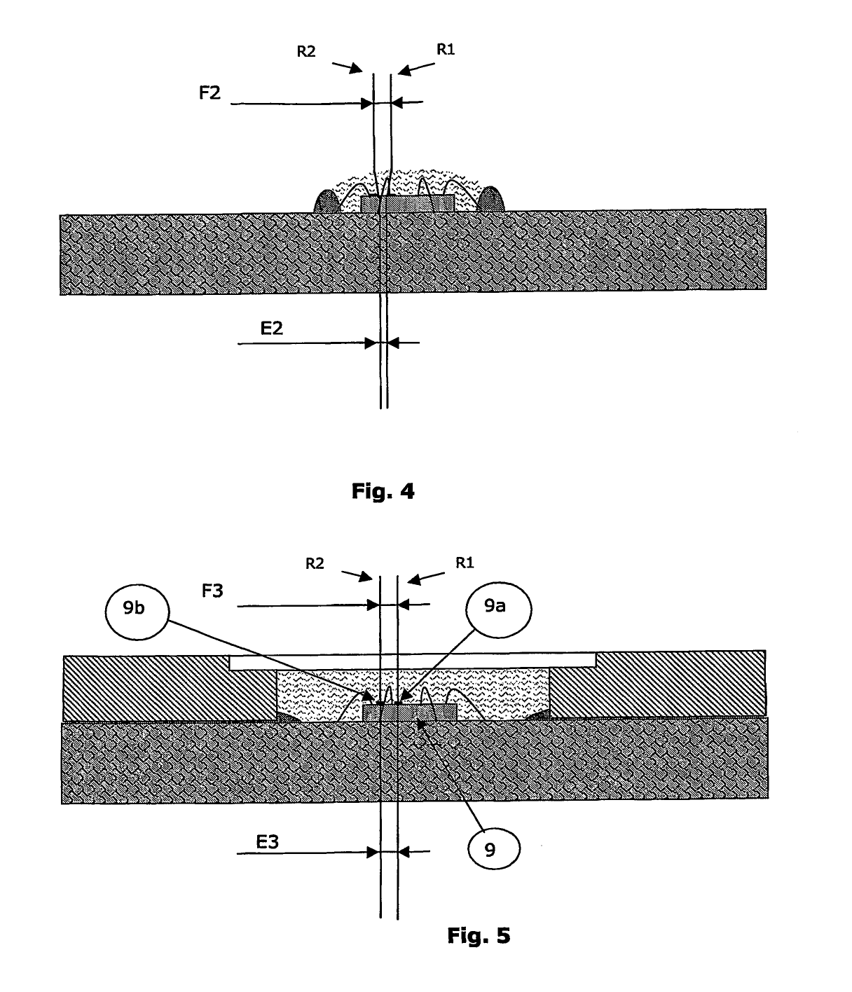

This is problematic in particular when the transducer has to receive two (or more) light rays whose separation F2 is precisely determined by the spacing of respective sensors, but would be modified (at E2) during their path through the optical glue 11 after having passed through an outer surface of non-plane optical cement, as may be clearly seen in FIG. 4.

Finally, especially because of the imprecision in depositing the bead of glue 12, it may happen that the conducting wires 10 that connect the integrated circuit 9 to the printed circuit board 8 are partly covered by the bead of glue 12, in addition to their normal encapsulation by the optical glue 11. In this case, owing to the different expansions of the optical glue 11 and the bead of glue 12, there is a risk of one of the conducting wires 10 breaking at each change in temperature (for example between the case in which it is in operation and when it is not in operation).

To solve these problems in particular, the invention proposes a device suitable for reading an optical disc, comprising an optical body with means for transmitting at least one light ray, a board having one face turned towards the optical body and bearing an optical sensor intended to receive the light ray, and a spacer carried by the said face and defining, with said face, a cavity that houses the optical sensor, the cavity being at least partly filled with an optical glue and the spacer being fastened to the optical body.

In a preferred embodiment, the spacer and the optical body are made in the same material, so as in particular to improve their relative fastening.

The invention also proposes a photoelectric transducer comprising a board bearing an optical sensor on one face, and a spacer carried by the said face and defining, with said face, a cavity that houses the optical sensor, the cavity being at least partly filled with an optical glue.

Preferably, at least one wall of the spacer defining the cavity is straight, especially in cross section in a plane perpendicular to the board, in particular so as to obtain a plane outer surface of optical cement.

Within the same concept, at least one wall of the spacer defining the cavity may be essentially perpendicular to the general plane of the board.

According to one possible solution, and especially so as to avoid any contact with the optical glue, the cavity includes an enlarged upper part.

The invention proposes a method of producing a photoelectric transducer, comprising the following steps:
providing a spacer with a recess in a rigid material;
mounting the spacer on a board bearing at least an optical sensor in such a way that the optical sensor is located in the recess; and
filling at least part of the recess with an optical glue.
   The invention also proposes a method of producing a device or optical pick up suitable for reading an optical disc, comprising the following steps:
production of a spacer that includes a recess in a rigid material;
mounting of the spacer on a board bearing an optical sensor in such a way that the optical sensor is located in the recess;
filling of at least part of the recess with an optical glue;
fastening of the spacer to an optical body of the device.

Other features of the invention will become apparent in the light of the following description given with reference to the appended drawings in which:

FIG. 1 shows a first known solution for producing and mounting a photoelectric transducer in an optical disc read device;

FIG. 2 shows a second known solution for producing and mounting a photoelectric transducer in an optical disc read device;

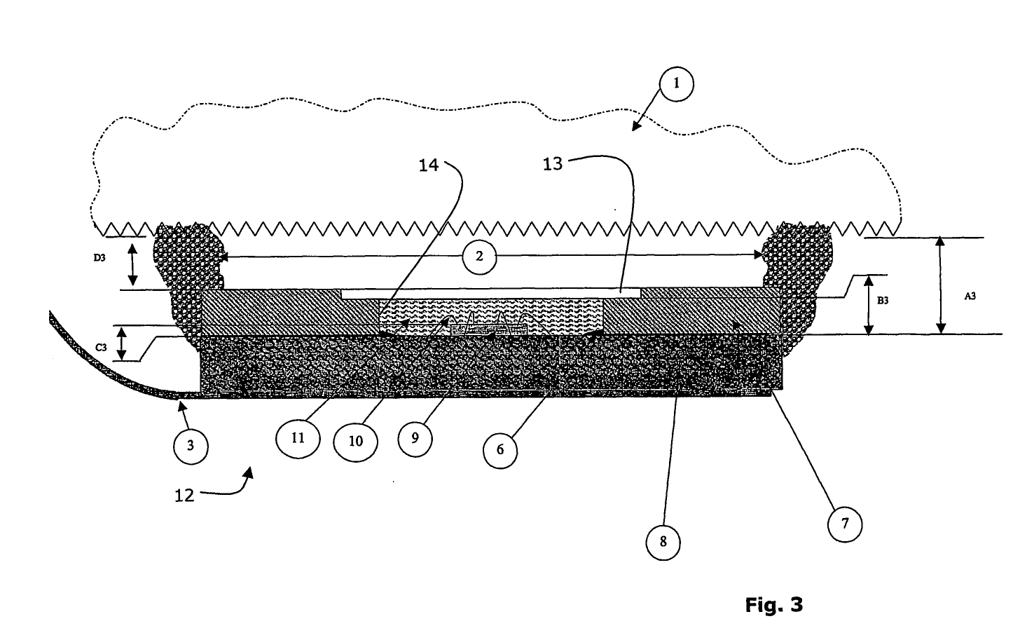

FIG. 3 shows a photoelectric transducer produced and mounted in an optical disc read device according to the teachings of the invention;

FIG. 4 is a detail of FIG. 2; and

FIG. 5 shows the detail corresponding to FIG. 3.

The read device, that part of which relevant to the invention is shown in FIGS. 3 and 5, comprises an optical body 1, which transmits two light rays R₁, R₂ in the direction of a photoelectric transducer 12 precisely directed at two optical sensors 9a and 9b carried by an integrated circuit 9 of the transducer 12, as is clearly visible in FIG. 3. The external parts of the optical body 1 are made for example of plastic.

Each light ray has a specific function, for example the reading of optical discs to the CD standard in the case of the ray R₁ and the reading of optical discs to the DVD standard in the case of the ray R₂. The light rays R₁ and R₂ may have different wavelengths for example 780 μm for CD standard and 635 μm for DVD standard.

The photoelectric transducer 12 includes a printed circuit board 8 (or PCB), a first main face of which carries the integrated circuit or die 9 and the second main face of which carries a flexible board 3, which is extended beyond the printed circuit board 8 as a connector (not shown) intended to ensure that the transducer 12 is connected to the other electronic circuits of the read device.

When the transducer 12 is mounted in the read device, the first main face of the printed circuit board 8 is directed towards the optical body 1.

The first main face carries a spacer 7, the central part of which is recessed and thus forms, with the first main face, a cavity open towards the optical body 1. The integrated circuit 9, carried by the first main face, is therefore placed inside the cavity. The width of the recess is such that all the connection wires 10 of the integrated circuit 9 be housed inside the recess, and there is no risk of having said connection wires be in contact with the spacer 7.

The spacer 7 is preferably made of the same material as the external parts of the optical body 1, for example made of the same plastic. Advantageously, the spacer 7 is made as a rigid separate part, for example a moulded part, which is then fastened to the printed circuit board 8. It may thus have a well-defined shape.

The spacer 7 may for example be fastened to the printed circuit board 8 by snap-fastening, with interposition of an impermeable adhesive 6 if necessary. Of course, other fastening means may be used.

Preferably, the central recess of the spacer 7 includes a lower part having a first width that houses the integrated circuit 9 and an upper part 13 having a second width, greater than the first width.

At least part of the cavity, here the lower part of the central recess, is filled with an optical glue 11 transparent to the light rays used. For instance, one may use an optical glue which has low viscosity, so the filling of the recess in the spacer 7 can be obtained easily with a plane surface. The hardening of the optical glue 11 may be done by heat or by UV light rays depending on the nature of the glue. Advantageously, the width of the recess surrounding the integrated circuit 9 is big enough to efficiently contribute to the realisation of the plane surface of the optical glue 11.

Advantageously, the walls 14 of the cavity that are formed by the spacer 7 are straight, preferably essentially perpendicular to the plane of the first main face of the printed circuit board 8. The straight walls 14 will interact with the optical glue 11 at its initial fluid stage, so that the superficial tension of the optical glue would lead the glue to go up alone the straight walls 14, so that it may offset at least partially the contraction of the optical glue alone the straight walls 14 due to hardening process. At least the useful area of the upper surface of the optical glue 11 receiving the light rays R₁ and R₂ is plane, essentially parallel to the first main surface of the printed circuit board 8, and the light rays R₁ and R₂ received from the optical body 1 maintain a constant distance (F3=E3 in FIG. 5) during their path through this surface and in the optical glue 11, so as to impinge respectively the optical sensors 9a and 9b without mis-alignments, as can be clearly seen in FIG. 5. In other words, when using a laser source emitting two light rays R₁ and R₂ which arrive either separately or simultaneously to the photoelectric transducer 12, they should be received correctly by the respective corresponding photo sensors 9a and 9b which are mounted at a given distance from each other. Conversely, the solution illustrated in FIG. 4 does not allow such possibility, as it is impossible to avoid misalignment between light rays and their respective photo sensors.

The upper part 13 of the central recess in the spacer 7 makes it improbable for there to be any contact with the upper face of the optical glue 11, which would degrade the quality of the surface, especially when mounting the transducer 12 on the optical body 1.

The photoelectric transducer 12 is fastened to the optical body 1, for example by means of a fastening adhesive 2, principally at the spacer 7, as can be clearly seen in FIG. 3. Thanks to the preferred use of the same material for the spacer 7 and the external part of the optical body 1 that houses it, the fastening is particularly quick, precise and robust.

Moreover, for the same integrated circuit 9/optical body 1 distance (A2 in FIG. 2 and A3 in FIG. 3, A2=A3), the distance D3 between the spacer 7 and the optical body 1 is smaller compared with the solution shown in FIG. 2, and may thus be of the order of the distance D1 between the package 5 and the optical body 1 in the solution shown in FIG. 1, thereby ensuring better precision and mechanical integrity.

Moreover, it may also be pointed out that the use, for the central recess in the spacer 7 of straight walls and its precise fastening (contrary to the bead of glue shown in FIGS. 2 and 4) make it possible for the central recess to be precisely located with respect to the conducting wires 10, which has the effect of avoiding any risk of the conducting wires 10 breaking, as indicated above.

1. Method of producing a photoelectric transducer, having the steps of:
providing a spacer with a recess in a rigid material;
mounting the spacer on a board bearing at least an optical sensor in such a way that the optical sensor is located in the recess;
filling at least part of the recess with an optical glue, and
hardening the optical glue,
wherein the width of the recess is such large that after hardening the surface of the optical glue is plane at least above the optical sensor.

2. Photoelectric transducer, including a spacer with a recess in a rigid material, the spacer being mounted on a board bearing at least an optical sensor in such a way that the optical sensor is located in the recess, at least part of the recess being filled with an optical glue, wherein the width of the recess is such large that the surface of the hardened optical glue is plane at least above the optical sensor.

3. Optical pick up suitable for reading an optical disc, comprising:
a photoelectric transducer according to claim 2, and
an optical body with means for transmitting at least one light ray to the optical sensor through the optical glue, the spacer of the photoelectric transducer being fastened to the optical body.

4. Optical pick up according to claim 3, wherein the wall of the spacer defining the recess is perpendicular to the board.

5. Optical pick up according to claim 4, wherein it uses at least two light rays, and at least two optical sensors on the board each designed to receive one light ray, the spacing between the centers of the optical sensors being the same as the spacing between the corresponding light rays at the surface of the optical glue.

6. Optical pick up according to claim 3, wherein the spacer and the optical body are produced in the same material.
